(19) United States
(12) Patent Application Publication
(10) Pub. No.: US 2025/0183011 A1
(43) Pub. Date: Jun. 5, 2025

(54) LIQUID COOLING PLATE FOR COOLING OF DIELECTRIC WINDOW OF A SUBSTRATE PROCESSING SYSTEM

(71) Applicant: LAM RESEARCH CORPORATION, Fremont, CA (US)

(72) Inventors: Hanry ISSAVI, San Jose, CA (US); Allan RONNE, Santa Clara, CA (US); Jerrell K. ANTOLIK, Livermore, CA (US)

(21) Appl. No.: 18/868,019

(22) PCT Filed: May 16, 2023
(86) PCT No.: PCT/US2023/022353

§ 371 Date: Nov. 21, 2024

Related U.S. Application Data
(60) Provisional application No. 63/349,745, filed on Jun. 7, 2022.

(51) Int. Cl. H01J 37/32; H01L 21/683

(52) U.S. Cl. CPC H01J 37/32522; H01J 37/321; H01J 2237/002; H01L 21/683

(57) ABSTRACT

A substrate processing system includes a processing chamber including a dielectric window and a substrate support. A gas delivery device is located in the processing chamber between the dielectric window and the substate support. An inductive coil arranged outside of the processing chamber adjacent to the dielectric window. A cooling plate is arranged between the inductive coil and the dielectric window and configured to flow liquid coolant.

### CROSS-REFERENCE TO RELATED APPLICATIONS

This application claims the benefit of U.S. Provisional Application No. 63/349,745, filed on Jun. 7, 2022. The entire disclosure of the above application is incorporated herein by reference.

### FIELD

The present disclosure relates to substrate processing systems and more particularly to a liquid cooling plate for cooling a dielectric window of a substrate processing system.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

During manufacturing of substrates such as semiconductor wafers, a series of substrate treatments such as deposition, etching and/or cleaning processes are performed on the substrate. The substrate is typically delivered by a robot onto a substrate support such as an electrostatic chuck (ESC) or a pedestal in a processing chamber. Process gases are introduced into the processing chamber via a gas distribution device and plasma may be struck in the processing chamber to enhance chemical reactions.

In some examples, the process is an etch process such an inductively coupled plasma (ICP) process. In ICP processes, one or more inductive coils are arranged outside of the processing chamber adjacent to a dielectric window of the processing chamber. RF power is supplied to the inductive coils while the process gases are being supplied inside of the processing chamber. The inductive coils generate a magnetic field inside of the processing chamber, which ignites plasma.

Heating of the dielectric window occurs during plasma processing. In some substrate processing systems, cooling fans or air amplifiers including plenums are used to supply cool air across the dielectric window during plasma processing. The cooling fans and/or air amplifiers create a lot of noise and consume a significant amount of clean dry air (CDA). Further, the cooling fans or air amplifiers do not provide sufficient cooling for higher power processes.

### SUMMARY

A substrate processing system includes a processing chamber including a dielectric window and a substrate support. A gas delivery device is arranged in the processing chamber between the dielectric window and the substate support. An inductive coil is arranged outside of the processing chamber adjacent to the dielectric window. A cooling plate is arranged between the inductive coil and the dielectric window and configured to flow liquid coolant.

In other features, the cooling plate includes N liquid flow channels configured to flow the liquid coolant in N zones, where N is an integer greater than one. The cooling plate includes a first portion including the N liquid flow channels and a second portion bonded to the first portion to enclose the N liquid flow channels. Facing surfaces of the cooling plate and the dielectric window are in direct contact.

In other features, a first portion of the cooling plate including the N liquid flow channels is integrated with the dielectric window. A second portion is bonded to the first portion to enclose the N liquid flow channels. A thermal conducting layer is arranged between the cooling plate and the dielectric window. The thermal conducting layer comprises silicone. The cooling plate is made of ceramic.

In other features, N temperature sensors are configured to sense N temperatures in the N zones, respectively. N valves are configured to vary supply of the liquid coolant to the N zones, respectively. A controller is configured to adjust the N valves in response to the N temperature sensors.

In other features, N heaters are configured to selectively heat the liquid coolant delivered to the N zones, respectively. A controller is configured to adjust the N heaters in response to the N temperature sensors, respectively.

In other features, the inductive coil includes N sets of coils. The N sets of coils are aligned with the N zones of the cooling plate. At least one of the N liquid flow channels is bifilar. At least one of the N liquid flow channels is non-bifilar.

A method for cooling a dielectric window of a substrate processing system includes providing a processing chamber including a dielectric window, a substrate support, and a gas delivery device located between the dielectric window and the substate support; arranging an inductive coil outside of the processing chamber adjacent to the dielectric window; arranging a cooling plate between the inductive coil and the dielectric window; and flowing liquid coolant through the cooling plate.

In other features, the cooling plate includes N liquid flow channels configured to flow liquid coolant in N zones, where N is an integer greater than one. The cooling plate includes a first portion including the N liquid flow channels and a second portion bonded to the first portion. Facing surfaces of the cooling plate and the dielectric window are in direct contact.

In other features, a first portion of the cooling plate including the N liquid flow channels is integrated with the dielectric window. The method includes bonding a second portion to the first portion to enclose the N liquid flow channels. The method includes arranging a thermal conducting layer between the cooling plate and the dielectric window.

In other features, the cooling plate is made of ceramic. The method includes sensing N temperatures in the N zones, respectively; and varying supply of the liquid coolant to the N zones in response to the N temperatures, respectively. The method includes sensing N temperatures in the N zones, respectively; and selectively heating the liquid coolant delivered to the N zones in response to the N temperatures, respectively.

In other features, the inductive coil includes N sets of coils and further comprising aligning the N sets of coils with the N zones of the cooling plate, respectively. At least one of the N liquid flow channels is bifilar. At least one of the N liquid flow channels is non-bifilar.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1A is a functional block diagram of an example of a substrate processing system including a liquid cooling plate for cooling of a dielectric window of a processing chamber according to the present disclosure;

FIG. 1B is an example of an inductive coil including a set of inner coils and a set of outer coils;

FIG. 2 is a more detailed functional block diagram of an example of the liquid cooling plate including multiple zones and a control system for a cooling fluid supply to the liquid cooling plate;

FIG. 3 is a plan view of an example of liquid flow channels of a liquid cooling plate including multiple zones according to the present disclosure;

FIG. 4A is a side view of an example of a cooling plate arranged above a dielectric window according to the present disclosure;

FIG. 4B is a side view of an example of a cooling plate arranged above a thermal coupling layer and a dielectric window according to the present disclosure;

FIG. 4C is a perspective view of an example of liquid flow channels formed in one portion of the liquid cooling plate; and

FIG. 5 is a side view of an example of a portion of a cooling plate (including liquid flow channels) that is integrated with a dielectric window according to the present disclosure.

In the drawings, reference numbers may be reused to identify similar and/or identical elements.

### DETAILED DESCRIPTION

When performing inductively coupled plasma (ICP) processing, inductive coils are arranged outside of the processing chamber adjacent to a dielectric window of the processing chamber. Process gas is supplied in the processing chamber via a showerhead plate, gas injector or other gas delivery device. RF signals are supplied to the inductive coils, which generate magnetic fields that pass through the dielectric window into the processing chamber. The magnetic fields ignite the process gases to create plasma. During substrate processing, heat generated by the plasma and the inductive coils (excited by RF signals transmitted by the inductive coils) increases a temperature of the dielectric window.

The temperature of the dielectric window and other components may be controlled to minimize mechanical stress, preventing damage, maintaining process uniformity, etc. For example, an air plenum may be arranged above the dielectric window and air is circulated within the air plenum to cool the dielectric window. For some processes, relatively high air flow is required to provide sufficient cooling of the dielectric window, resulting in undesirable noise levels. To reduce contamination, clean dry air (CDA) is typically used. As the plasma power increases, the temperature and mechanical stress also increase and cooling provided by air flow may be insufficient.

A liquid cooling plate according to the present disclosure is arranged adjacent to the dielectric window (or integrated with the dielectric window). The liquid cooling plate includes liquid flow channels arranged in two or more zones. A control system monitors a temperature of the two or more zones and adjusts liquid flow, liquid pressure or liquid temperature supplied to the cooling plate.

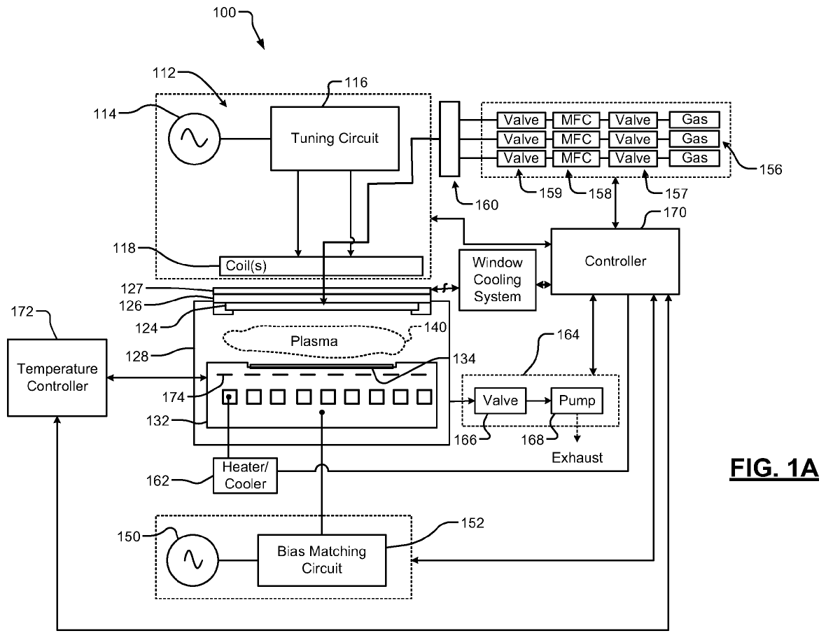

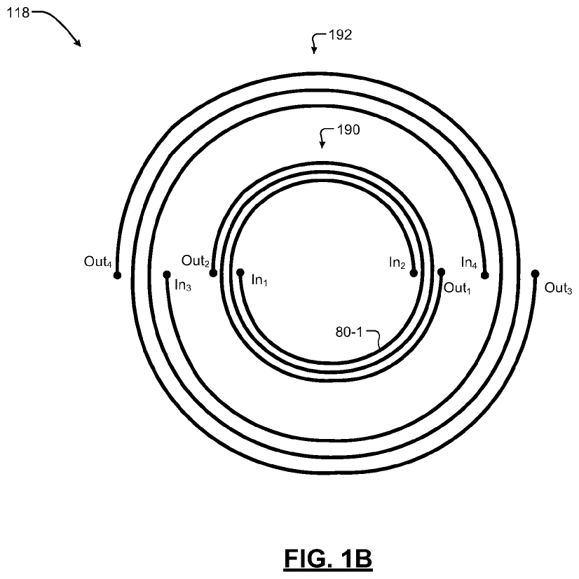

Referring now to FIGS. 1A and 1B, an example of a substrate processing system 100 including the liquid cooling plate is shown. The substrate processing system 100 includes a coil driving circuit 112. As shown, the coil driving circuit 112 includes an RF source 114 and a tuning circuit 116. The tuning circuit 116 may be directly connected to one or more inductive coils 118. The tuning circuit 116 tunes an output of the RF source 114 to a desired frequency and/or a desired phase, matches an impedance of the inductive coils 118 and optionally splits power between two or more sets of the inductive coils 118 (if used). A liquid cooling plate 127 is arranged adjacent to the dielectric window 126 to cool the dielectric window 126.

The substrate processing system 100 includes a showerhead 124 and a dielectric window 126. In some examples, the showerhead 124 includes a gas plate defining an internal plenum and a plurality of gas through holes. The showerhead 124 is arranged between the dielectric window 126 and a substrate support 132. In some examples, the dielectric window 126 and the showerhead 124 are made of ceramic or another dielectric material.

The substrate support 132 may include an electrostatic chuck (ESC), or a mechanical chuck or other types of chuck. In operation, a process gas is supplied to the processing chamber 128 via the showerhead 124 (e.g., a plurality of holes passing through the gas plate) and plasma 140 is generated inside of the processing chamber 128. For example, a magnetic field is transmitted by the inductive coils through the dielectric window 126 into the interior of the processing chamber 128. The magnetic field excites gas molecules within the processing chamber 128 to generate plasma 140. The plasma 140 etches an exposed surface of the substrate 134. An RF source 150 and a bias matching circuit 152 may be used to bias the substrate support 132 during operation to control ion energy.

A gas delivery system 154 may be used to supply a process gas mixture to the processing chamber 128. The gas delivery system 154 may include process and inert gas sources 156 (e.g., including deposition gases, etch gases, carrier gases, inert gases, etc.), valves 157, mass flow controllers 158, valves 159 and a manifold 160. A heater/cooler 162 may be used to heat/cool the substrate support 132 to a predetermined temperature. An exhaust system 164 includes a valve 166 and pump 168 to remove reactants from the processing chamber 128 by purging or evacuation and/or to control pressure in the processing chamber.

A controller 170 may be used to control the process. The controller 170 monitors system parameters and controls delivery of the gas mixture, striking, maintaining and extinguishing the plasma, removal of reactants, and so on. Additionally, the controller 170 may control various aspects of the coil driving circuit 112, the RF source 150, etc.

In FIG. 1B, an example of the inductive coil 118 including a set of inner coils 190 and a set of outer coils 192 is shown. While two sets of coils are shown, a single coil, a single set of coils or additional sets coils can be used. In some examples, the liquid cooling plate 127 includes multiple zones. In some examples, the number of zones corresponds to the number of coils or coil sets.

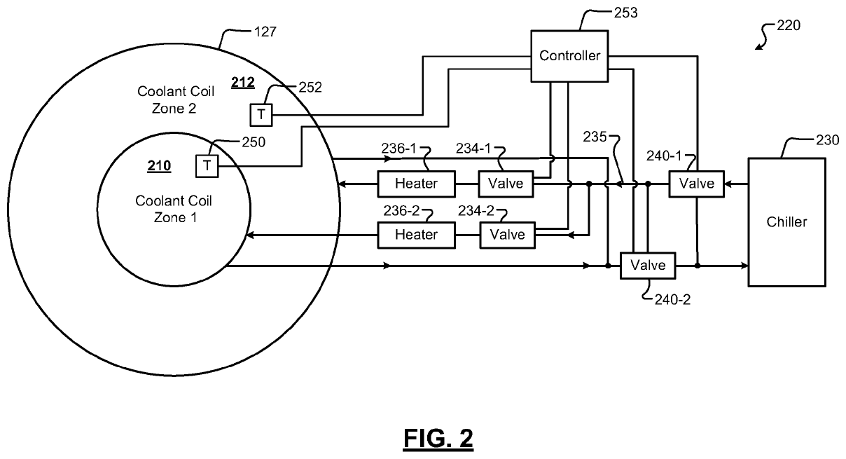

Referring now to FIG. 2, an example of the liquid cooling plate 127 and a control system 220 for a cooling fluid supply to the liquid cooling plate 127 are shown. In this example, the liquid cooling plate 122 includes a first or inner zone including a coolant coil 210 and a second or outer zone including a coolant coil 212. While two zones are shown in FIG. 2, additional zones can be used.

A chiller 230 provides cooled liquid to a valve 234-1 and a heater 236-1 via conduit 235 to supply cooling fluid to the coolant coil 212 in the second zone. In some examples, a bypass valve 240-1 is arranged between the chiller 230 and the valve 234-1. In other examples, the bypass valve 240-1 is omitted. The conduit 235 also supplies a second valve 234-2 and a second heater 236-2 that supply cooling fluid to coolant coil 210 in the first zone. In some examples, the valves 234-1 and 234-2 are variable valves that are controlled to vary fluid flow rate and/or pressure. In some examples, the heaters 236-1 and 236-2 comprise resistive heaters.

In some examples, the temperature of the zones can be monitored. A temperature sensor 250 is arranged to sense a temperature of the coolant coil 210 in the first zone. A temperature sensor 252 is arranged to sense a temperature of the coolant coil 212 in the second zone. A controller 253 monitors the temperatures sensed by the temperature sensors 250, 252 and adjusts the valves 234-1 and 234-2 to independently vary the flow rate and/or pressure of the liquid coolant flowing through the coolant coil 210 and/or the coolant coil 212, respectively. The controller 253 also adjusts the power to the heaters 236-1 and 236-2 in response to the sensed temperature.

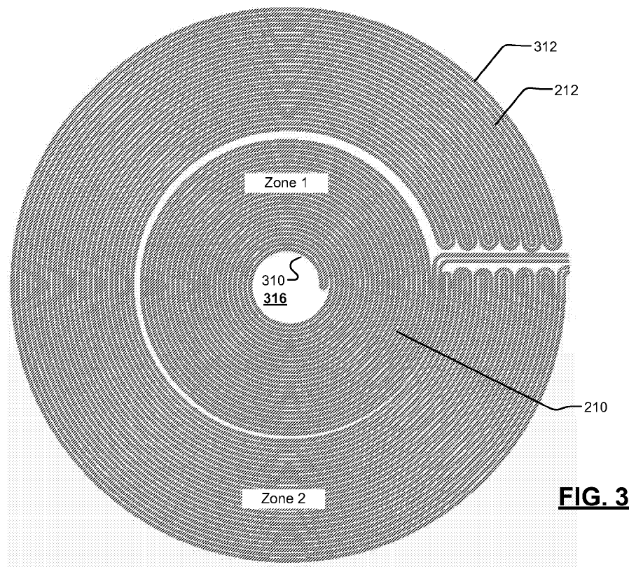

Referring now to FIG. 3, an example of cooling coils for a liquid cooling plate including multiple zones is shown. In this example, a cooling coil 310 located in the first zone is bifilar. The cooling coil 310 optionally includes a central area 316 that is open. A cooling coil 312 located in the second zone is also bifilar. In some examples, the cooling coils 310 and 312 include inlets and outlets that are arranged adjacent to one another at a radially outer side of the cooling coil 312. While both of the cooling coils 310 and 312 are shown as bifilar, one or both can be non-bifilar.

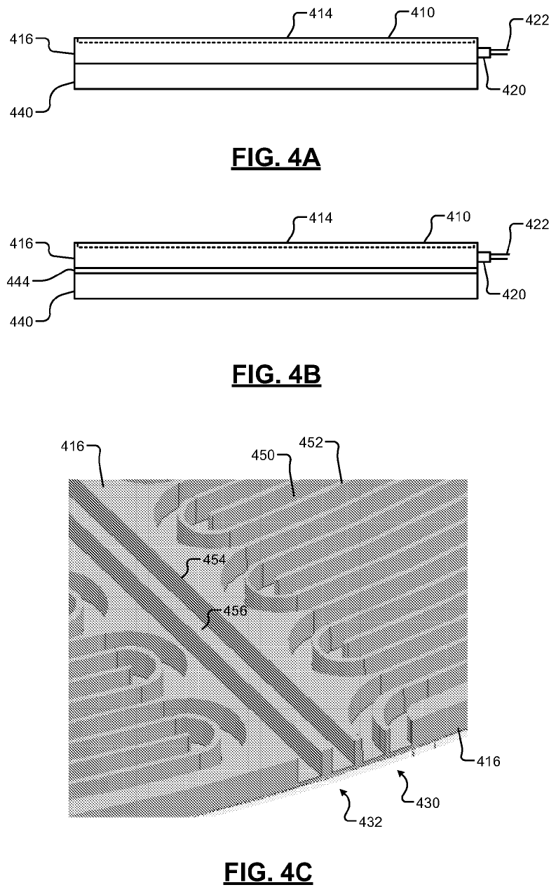

Referring now to FIGS. 4A and 4B, an example of a cooling plate 410 arranged above a dielectric window 440 is shown. The cooling plate 410 includes the cooling coils as described above. The cooling plate 410 is formed by a lower portion 416 including liquid flow channels defined therein. An upper portion 414 is bonded to the lower portion to enclose upper surfaces of the liquid flow channels. In FIG. 4A, a bottom surface of the cooling plate 410 is in direct contact with an upper surface of the dielectric window 440.

In FIG. 4B, a thermally-conducting layer 444 is optionally arranged between a bottom surface of the cooling plate 410 and an upper surface of the dielectric window 440 to allow thermal transfer and relative movement. In some examples, the thermally-conducting layer 444 can also be electrically insulating. In some examples, the thermally-conducting layer 444 is made of silicone, although other materials can be used.

Referring now to FIG. 4C, an example of liquid flow channels in the liquid cooling plates are shown. The lower portion 416 includes first liquid flow channels 450 corresponding to the second zone and sidewalls 452 arranged between the first liquid flow channels 450 and/or second liquid flow channels 454. The lower portion 416 further includes the second liquid flow channels 454 including side walls 456 that are arranged between the second liquid flow channels 454 and/or the first liquid flow channels 450. Cooling liquid flows separately through the first liquid flow channels 450 and the second liquid flow channels 454 to exchange heat with the dielectric window in the corresponding zones.

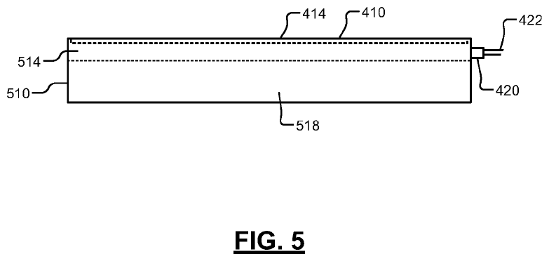

Referring now to FIG. 5, an example of an integrated cooling plate and dielectric window 510 is shown. The integrated cooling plate and dielectric window 510 includes the cooling coils as shown above. The integrated cooling plate and dielectric window 510 includes a first portion 516 including cooling liquid flow channels defined therein. A second portion 518 of the integrated cooling plate and dielectric window 510 acts as a dielectric window. A third portion 514 is bonded to the first portion 516 to enclose an upper surface of the liquid flow channels. Making the cooling plate and the dielectric window using the same material means that the coefficients of thermal expansion (CTEs) of the cooling plate and the dielectric window are matched and behave similarly when exposed to heating or cooling, which reduces mechanical stress.

As can be appreciated, use of the liquid cooled plate instead of air cooling significantly improves cooling performance of the dielectric window and allows higher power levels to be used within the ICP chamber.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate processing system comprising:
a processing chamber including a dielectric window and a substrate support;
a gas delivery device located in the processing chamber between the dielectric window and the substate support;
an inductive coil arranged outside of the processing chamber adjacent to the dielectric window; and
a cooling plate arranged between the inductive coil and the dielectric window and configured to flow liquid coolant.

2. The substrate processing system of claim 1, wherein the cooling plate includes N liquid flow channels configured to flow the liquid coolant in N zones, where N is an integer greater than one.

3. The substrate processing system of claim 2, wherein the cooling plate includes a first portion including the N liquid flow channels and a second portion bonded to the first portion to enclose the N liquid flow channels.

4. The substrate processing system of claim 2, wherein facing surfaces of the cooling plate and the dielectric window are in direct contact.

5. The substrate processing system of claim 2, wherein a first portion of the cooling plate including the N liquid flow channels is integrated with the dielectric window and further comprising a second portion bonded to the first portion to enclose the N liquid flow channels.

6. The substrate processing system of claim 1, further comprising a thermal conducting layer arranged between the cooling plate and the dielectric window.

7. The substrate processing system of claim 6, wherein the thermal conducting layer comprises silicone.

8. The substrate processing system of claim 1, wherein the cooling plate is made of ceramic.

9. The substrate processing system of claim 2, further comprising N temperature sensors configured to sense N temperatures in the N zones, respectively.

10. The substrate processing system of claim 9, further comprising N valves configured to vary supply of the liquid coolant to the N zones, respectively.

11. The substrate processing system of claim 10, further comprising a controller configured to adjust the N valves in response to the N temperature sensors.

12. The substrate processing system of claim 9, further comprising N heaters configured to selectively heat the liquid coolant delivered to the N zones, respectively.

13. The substrate processing system of claim 12, further comprising a controller configured to adjust the N heaters in response to the N temperature sensors, respectively.

14. The substrate processing system of claim 2, wherein:
the inductive coil includes N sets of coils; and
the N sets of coils are aligned with the N zones of the cooling plate.

15. The substrate processing system of claim 2, wherein at least one of the N liquid flow channels is bifilar.

16. The substrate processing system of claim 2, wherein at least one of the N liquid flow channels is non-bifilar.

17. A method for cooling a dielectric window of a substrate processing system, comprising:
providing a processing chamber including a dielectric window, a substrate support, and a gas delivery device located between the dielectric window and the substate support;
arranging an inductive coil outside of the processing chamber adjacent to the dielectric window;
arranging a cooling plate between the inductive coil and the dielectric window; and
flowing liquid coolant through the cooling plate.

18. The method of claim 17, wherein the cooling plate includes N liquid flow channels configured to flow liquid coolant in N zones, where N is an integer greater than one.

19. The method of claim 18, wherein the cooling plate includes a first portion including the N liquid flow channels and a second portion bonded to the first portion.

20. The method of claim 17, wherein facing surfaces of the cooling plate and the dielectric window are in direct contact.

21. The method of claim 18, wherein a first portion of the cooling plate including the N liquid flow channels is integrated with the dielectric window and further comprising bonding a second portion to the first portion to enclose the N liquid flow channels.

22. The method of claim 17, further comprising arranging a thermal conducting layer between the cooling plate and the dielectric window.

23. The method of claim 17, wherein the cooling plate is made of ceramic.

24. The method of claim 18, further comprising:
sensing N temperatures in the N zones, respectively; and
varying supply of the liquid coolant to the N zones in response to the N temperatures, respectively.

25. The method of claim 18, further comprising:
sensing N temperatures in the N zones, respectively; and
selectively heating the liquid coolant delivered to the N zones in response to the N temperatures, respectively.

26. The method of claim 18, wherein the inductive coil includes N sets of coils and further comprising aligning the N sets of coils with the N zones of the cooling plate, respectively.

27. The method of claim 18, wherein at least one of the N liquid flow channels is bifilar.

28. The method of claim 18, wherein at least one of the N liquid flow channels is non-bifilar.
